(19) United States
(12) Patent Application Publication
(10) Pub. No.: US 2015/0351238 A1
(43) Pub. Date: Dec. 3, 2015

(54) DEVICE AND DEVICE PACKAGE

(71) Applicant: SAMSUNG ELECTRO-MECHANICS CO., LTD., Suwon-Si (KR)

(72) Inventors: Hyung Gon KIM, Suwon-Si (KR); Katsushi YASUDA, Suwon-Si (KR); Soon Bum LEE, Suwon-Si (KR)

(21) Appl. No.: 14/565,162

(22) Filed: Dec. 9, 2014

(30) Foreign Application Priority Data
Jun. 3, 2014 (KR) 10-2014-0067382

(51) Int. Cl. H05K 1/11; H01L 41/047; H01L 41/053; H05K 5/00

(52) U.S. Cl. CPC H05K 1/11; H05K 5/00; H01L 41/047; H01L 41/053; H05K 2201/10083

(57) ABSTRACT

There are provided a device and a device package including a terminal electrically connected to a board and including one or more protrusion parts disposed on amounting surface on which the terminal is mounted on the board and the protrusion part is protruded from the mounting surface of the terminal.

### CROSS-REFERENCE TO RELATED APPLICATION

This application claims the benefit of Korean Patent Application No. 10-2014-0067382 filed on Jun. 3, 2014, with the Korean Intellectual Property Office, the disclosure of which is incorporated herein by reference.

### BACKGROUND

The present disclosure relates to a device and a device package.

A terminal may be electrically connected to a device included in an electronic apparatus and a board on which the device is mounted to enable an electrical connection to be formed between the device and the board. In addition, the terminal is bonded to the device and the board to serve to fix the device to the board.

Diversification, quality improvement, and increased levels of complexity have been demanded in electronic apparatuses. Therefore, it has been necessary for devices included in high performance electronic apparatuses to be miniaturized and to be provided with multiple functionalities. In addition, since a large number of devices may need to be mounted on a board, available mounting space on such a board may be insufficient, and the board requires flexible characteristics so as to be bent in various forms in order to comply with the diversification of the electronic apparatus.

A large number of miniaturized devices should be mounted on a predetermined mounting region of a board, and the mounted devices should be stably mounted on the board that is bent in various manners. Therefore, it has been necessary to obtain high adhesive strength between the device and the board in the case of mounting the device on the board by improving the terminal serving to electrically connect and bond the device and the board to one another.

Korean Patent Laid-Open Publication No. 2014-0051553 (Related Art Document) relates to a method of manufacturing a device package unit including an electrode pad electrically connected to a device.

### RELATED ART DOCUMENT

### (Patent Document 1) Korean Patent Laid-Open Publication No. 2014-0051553

### SUMMARY

An exemplary embodiment in the present disclosure may provide a device and a device package capable of being stably mounted on a board by including a protrusion part formed on a bonding surface of a terminal included in the device to improve adhesive strength.

According to an exemplary embodiment in the present disclosure, a device may include: a terminal; and one or more protrusion parts disposed on a mounting surface of the terminal.

The protrusion part may have a form protruded from the mounting surface of the terminal, and may have a stripe shape, a circular shape, or a polygonal shape when viewed on a plane.

The device may further include an electrode exposed to the outside of the device to thereby be electrically connected to the terminal.

The device may be a crystal device.

According to an exemplary embodiment in the present disclosure, a device package may include: a board; a terminal electrically connected to an electrode of the board; a device electrically connected to the terminal; and a case disposed so as to enclose the device, wherein the terminal includes one or more protrusion parts formed on a mounting surface by which the terminal is mounted on the board.

The protrusion part may have a form protruded from the mounting surface on which the terminal is mounted on the board among surfaces of the terminal, and second terminals may be disposed at four corners of a lower surface of the device, respectively.

The device may be a crystal device or a piezoelectric device.

### BRIEF DESCRIPTION OF DRAWINGS

The above and other aspects, features and other advantages in the present disclosure will be more clearly understood from the following detailed description taken in conjunction with the accompanying drawings, in which:

FIG. 1 is a perspective view of a terminal included in a device according to a first exemplary embodiment in the present disclosure;

FIG. 2 is a perspective view illustrating a device including the terminals of FIG. 1 according to a second exemplary embodiment in the present disclosure;

FIG. 3 is a perspective view illustrating a device including the terminals of FIG. 1 according to a third exemplary embodiment in the present disclosure;

FIG. 4 is a perspective view illustrating the device of FIG. 2 and a board having the device mounted thereon according to a fourth exemplary embodiment in the present disclosure;

FIG. 5 is an exploded perspective view of the device and the board of FIG. 4 shown without solders in order to clearly depict a coupling relationship between the device and the board;

FIG. 6 is a cross-sectional view of the device and the board of FIG. 4 taken along line A-A′ and illustrating coupling relationships between the device and terminals and between the terminals and electrodes of the board and disposition of solders;

FIGS. 7A through 7C are perspective views of a terminal included in a device according to fifth to seventh exemplary embodiments in the present disclosure;

FIG. 8 is a perspective view of a device package including a terminal according to an eighth exemplary embodiment in the present disclosure;

FIG. 9 is an exploded perspective view of the device package of FIG. 8 shown without solders in order to clearly depict coupling relationships between a device, terminals, and a board;

FIG. 10 is a cross-sectional view of the device package of FIG. 8 taken along line B-B′ and illustrating coupling relationships between the device and the terminals and between the terminals and electrodes of the board and disposition of solders;

FIG. 11 is a perspective view of a piezoelectric device package including a terminal according to a ninth exemplary embodiment in the present disclosure;

FIG. 12 is an exploded perspective view of the piezoelectric device package of FIG. 11 illustrating a connection relationship between a piezoelectric device and the terminal; and

FIG. 13 is a cross-sectional view of the piezoelectric device package of FIG. 11, taken along line C-C′, and illustrating a coupling relationship between an electrode of the piezoelectric device and a first terminal as well as a disposition of connection electrodes.

### DETAILED DESCRIPTION

Hereinafter, embodiments in the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Device

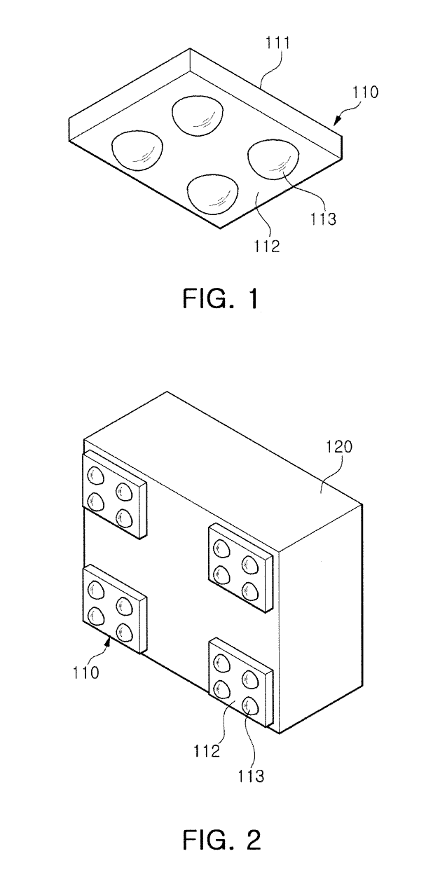

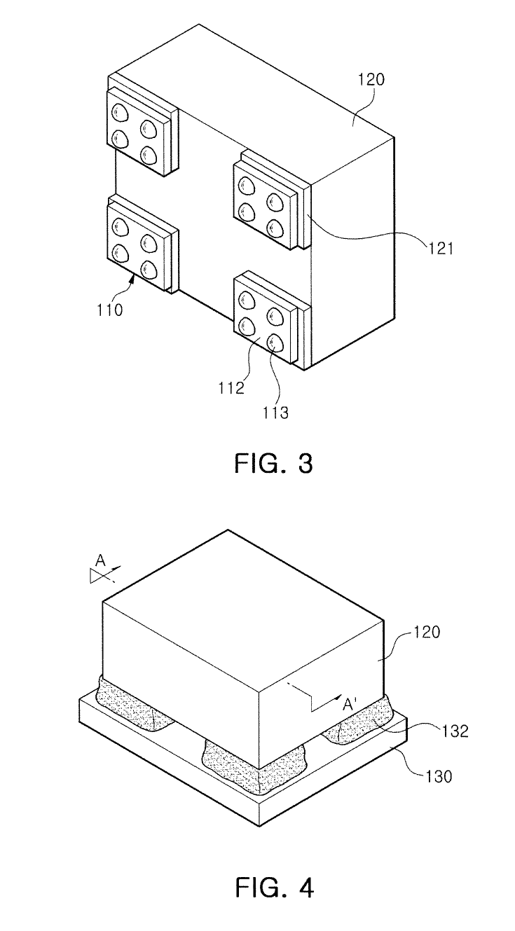

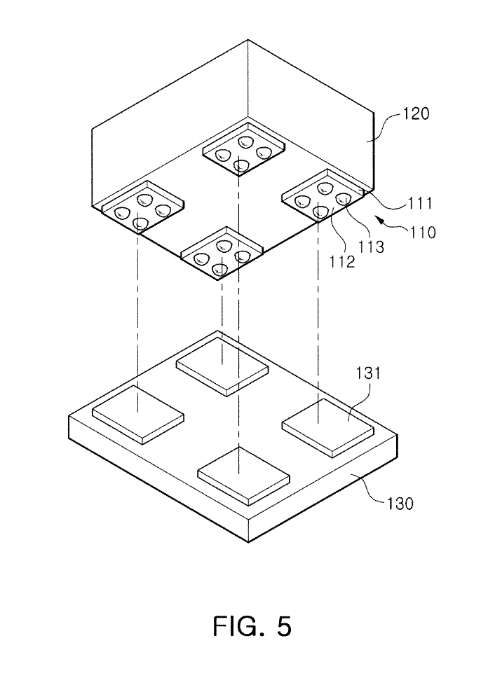

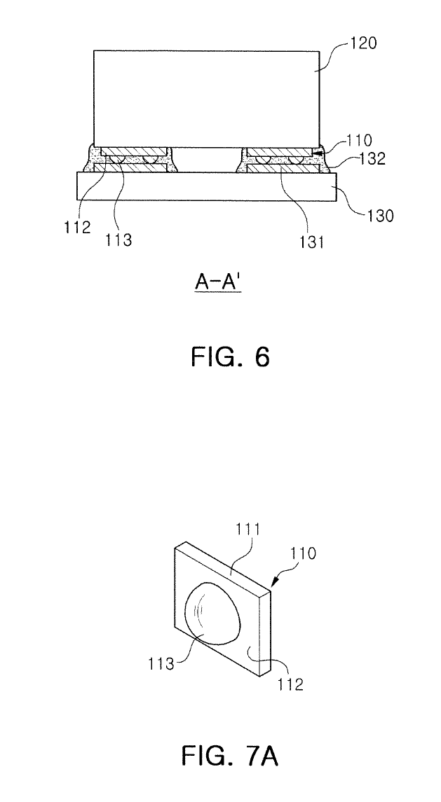

FIG. 1 is a perspective view of a terminal 110 included in a device according to a first exemplary embodiment in the present disclosure; and FIG. 2 is a perspective view illustrating a device 120 including the terminals 110 of FIG. 1 according to a second exemplary embodiment in the present disclosure. FIG. 3 is a perspective view illustrating a device 120 including the terminals 110 of FIG. 1 according to a third exemplary embodiment in the present disclosure; and FIG. 4 is a perspective view illustrating the device 120 of FIG. 2 and a board 130 having the device mounted thereon according to a fourth exemplary embodiment in the present disclosure. FIG. 5 is an exploded perspective view of the device 120 and the board 130 of FIG. 4 shown without solders 132 in order to clearlydepict a coupling relationship between the device 120 and the board 130. FIG. 6 is a cross-sectional view of the device 120 and the board 130 of FIG. 4 taken along line A-A′ and illustrating coupling relationships between the device 120 and terminals 110 and between the terminals 110 and electrodes 131 of the board and the disposition of solders 132.

Referring to FIGS. 2 through 4 and 6, the device 120 according to an exemplary embodiment in the present disclosure may include the terminals 110 and one or more protrusion parts 113 formed on mounting surfaces 112 of the terminals. The terminals 110 may be electrically connected to the board 130.

Referring to FIG. 3, the device according to a third exemplary embodiment in the present disclosure may further include electrodes 121 exposed to the outside thereof, in addition to the terminals including the protrusion parts. The device may be more easily bonded to the terminals 110 through the electrodes 121 that are separately provided.

The terminal 110 may be electrically connected to the device 120 through a bonding surface 111 thereof and be electrically connected to the board 130 having the device 120 mounted thereon through the mounting surface 112 thereof to enable an electrical connection between the device 120 and the board 130.

The device 120 may be a crystal device, a semiconductor device, an inductor, a capacitor, a piezoelectric device, or the like. However, the present disclosure is not limited thereto.

As the board 130 on which the device 120 is to be mounted, various boards may be used depending on a type of device to be mounted on the board, a kind of electronic apparatus including the device and the board, an intended use of the board, and the like.

Since the terminal 110 is electrically connected to the device 120 and the electrode 131 of the board on which the device 120 is mounted, a material of the terminal 110 may have an influence on efficiency of power supply between the device 120 and the board 130.

Therefore, the terminal 110 may be formed of a conductive material. In detail, the terminal 110 may be formed of a conductive material containing aluminum, copper, or the like, and a surface of the terminal 110 may be plated with tin (Sn), gold (Au), nickel (Ni), or lead (Pb). However, the present disclosure is not limited thereto.

FIG. 6 is a cross-sectional view of the device 120 and the board 130 of FIG. 4 taken along line A-A′ and illustrating coupling relationships between the device 120 and terminals 110 and between the terminals 110 and electrodes 131 of the board and disposition of solders 132.

A method of mounting the device 120 on the board 130 may be performed by a process of disposing the terminal 110 disposed on the device 120 so as to correspond to the electrode 131 of the board 130 and then bonding the terminal 110 and the electrode 131 of the board 130 to each other.

In detail, there may be a method of forming the solder 132 on the electrode 131 of the board, disposing the terminal 110, and performing a reflow process to bond the electrode 131 of the board 130 and the terminal 110 to each other, a method of adhering a bonding film between the electrode of the board 130 and the terminal 110 to bond the electrode of the board 130 and the terminal 110 to each other, a method of welding the electrode of the board 130 and the terminal 110 to each other, and the like. However, the present disclosure is not limited thereto.

Referring to FIG. 6, the terminal 110 according to a fourth exemplary embodiment in the present disclosure may be bonded to the board 130 by forming the solder 132 on the electrode 131 of the board and performing the reflow process.

In a process of bonding the terminal 110 to the electrode 131 of the board, a shape of the mounting surface 112 of the terminal 110 may have an influence on adhesive strength. In the case in which a bonding area of the mounting surface 112 of the terminal 110 is insufficient or a bonding shape thereof is poor, adhesive strength may be decreased, and the device 120 to which the terminal 110 is bonded may not be stably mounted.

In the case in which the electronic apparatus including the device and the board is miniaturized, since a space in which the device may be mounted on the board is insufficient, it may be necessary to stably mount the device in a narrow mounting space.

In addition, it may be required to increase the adhesive strength so that the device may be stably mounted on the board having flexible characteristics so as to be bent in various forms and used in the electronic apparatus.

In addition, in the electronic apparatus in which multifunctionality and complexity are demanded, a crystal device may be mainly used. Since one crystal device is connected to the board through a plurality of electrodes, a mounting space may be narrow. Therefore, a crack may occur in a bonding part between the crystal device and the board due to thermal impact caused by heat generated when the electronic apparatus is used. Therefore, it may be required to increase adhesive strength of a bonding part between the terminal of the crystal device and the electrode of the board in order to prevent the occurrence of the crack due to the thermal impact.

As described above, the terminal 110 included in the device 120 according to an exemplary embodiment in the present disclosure may include one or more protrusion parts 113 formed on the mounting surface 112 thereof bonded to the board 130 in order to increase the adhesive strength between the terminal 110 and the board 130.

A bonding area between the terminal 110 and the electrode 131 of the board may be increased through the protrusion part 113 to improve the adhesive strength. In other words, a surface on which the solder 132 and the terminal 110 are bonded to each other may be widened by the protrusion part 113 included in the terminal 110, such that the adhesive strength may be increased.

In addition, in the case in which pressure is applied to the board 130 or the board 130 is bent, stress occurring in a bonding part between the terminal 110 and the board 130 may be dispersed by the area increased by the protrusion part 113 and a shape of the protrusion part, such that the adhesive strength may be improved. For example, in the case in which the protrusion part 113 is formed in a stripe pillar shape having directionality in one direction, the terminal 110 having the protrusion part 113 may have strong adhesion strength with respect to transversal external force applied perpendicularly to a length direction of the stripe pillar shape.

As described above, the terminal 110 according to an exemplary embodiment in the present disclosure is used, such that the adhesion strength may be increased. Therefore, the device may be stably mounted even in a narrow mounting area. Therefore, the mounting area may be decreased, such that a degree of freedom in a design of the electronic apparatus may be increased, and the adhesive strength may be increased, such that reliability of the electronic apparatus may be improved.

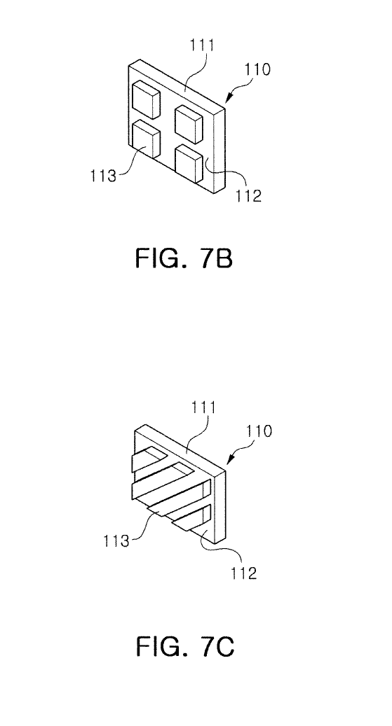

FIGS. 7A through 7C are perspective views of a terminal 110 included according to fifth to seventh exemplary embodiments in the present disclosure.

The protrusion part 113 included in the terminal 110 may have a form protruded from the mounting surface 112 on which the terminal 110 is mounted on the board 130 among surfaces of the terminal 110. The number of protrusion parts may be one as shown in FIG. 7A or be plural as shown in FIGS. 7B and 7C.

A shape of the protrusion part included in the terminal 110 may be a hemispherical shape as shown in FIG. 7A or a polygonal pillar shape as shown in FIG. 7B. In this case, any one polygonal pillar shape may be repeatedly formed or several polygonal pillar shapes may be alternately or randomly formed. Although the case in which the protrusion part has a rectangular pillar shape has been shown in FIG. 7B, the present disclosure is not necessarily limited thereto. In addition, the protrusion part may have a stripe pillar shape as shown in FIG. 7C.

The shape and the number of protrusion parts 113 are not particularly limited. The shape and the number of protrusion parts 113 may be various depending on a kind of device 120 on which the terminals 110 are disposed, a kind of board 130 on which the device 120 is mounted, or the like.

As shown in FIG. 7A, adhesive strength of the terminal 110 including the protrusion part 113 having the hemispherical shape may be further increased since a surface area of the protrusion part 113 is wider than those of the protrusion parts having other shapes.

The terminal 110 including the protrusion part 113 having the polygonal pillar shape or the protrusion part 113 having the stripe pillar shape with directivity in one direction as shown in FIGS. 7B and 7C may have strong adhesion strength with respect to the transversal external force applied perpendicularly to one surface of a polygon or the length direction of the stripe pillar shape. Therefore, even in the case in which deformation or warpage occurs in the board 130, high adhesive strength thereof may be maintained.

### Device Package

Next, a device package 200 including a terminal 210 according to another exemplary embodiment in the present disclosure will be described.

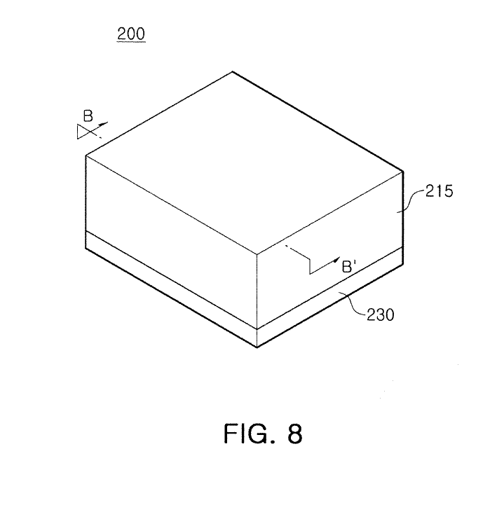

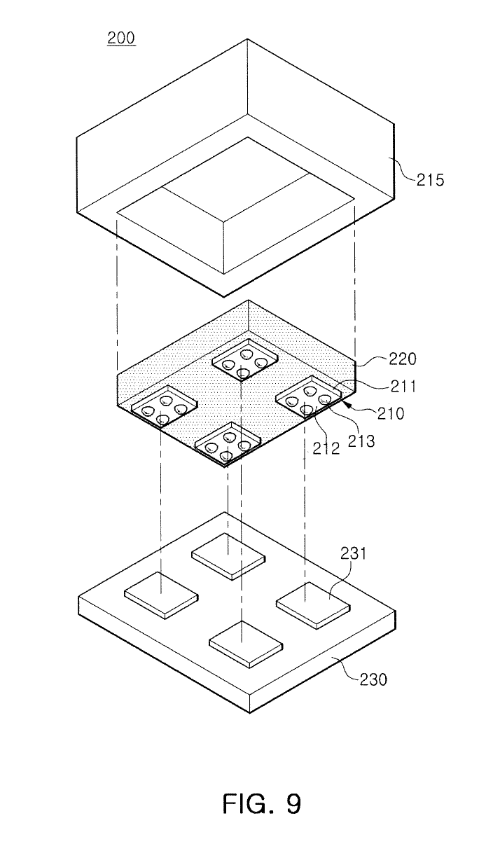

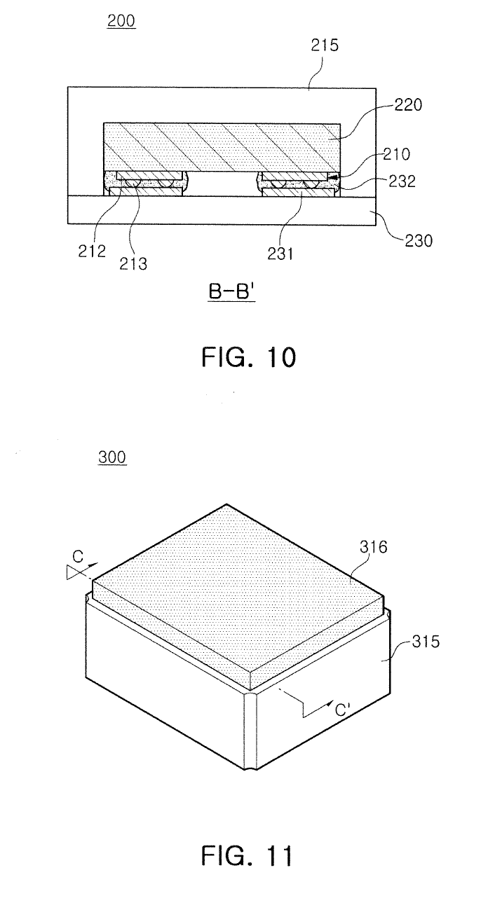

FIG. 8 is a perspective view of a device package 200 including a terminal 210 according to an eighth exemplary embodiment in the present disclosure; and FIG. 9 is an exploded perspective view of the device package 200 of FIG. 8 depicted without solders 232 in order to clearly depict coupling relationships between a device 220, terminals 210, and aboard 230. FIG. 10 is a cross-sectional view of the device package 200 of FIG. 8 taken along line B-B′ and illustrating coupling relationships between the device 220 and terminals 210 and between the terminals 210 and electrodes 231 of the board 230 and disposition of solders 232.

Referring to FIGS. 8 through 10, the device package 200 including the terminal 210 according to an eighth exemplary embodiment in the present disclosure may include the board 230 having the device 220 mounted thereon, the terminals 210 electrically connected to electrodes 231 of the board, the device 220 electrically connected to the terminals 210, and a case disposed so as to enclose the terminals 220, wherein the terminals 210 includes one or more protrusion parts 213 formed on amounting surface 212 thereof on which they are mounted on the board 230.

The device 220 included in the device package 200 according to an exemplary embodiment in the present disclosure may be a crystal device, a temperature device, a light emitting device, a surface acoustic wave device, a piezoelectric device, or the like. However, the present disclosure is not limited thereto.

The board 230 on which the device 220 is mounted may be formed of ceramic. The mounting surface 212 of the terminal 210 may be bonded to the electrode 231 of the board so as to correspond to the electrode 231 of the board. As a method of bonding the terminal 210 to the electrode 231 of the board, there may be provided a method of forming the solders on the electrode of the board, disposing the terminal, and performing a reflow process to bond the terminal to the electrode of the board, a method of adhering a bonding film between the electrode of the board and the terminal to bond the terminal to the electrode of the board, a method of welding the electrode of the board and the terminal to each other, and the like. However, the present disclosure is not limited thereto.

The device 220 may be isolated from the outside by the case 215. The case 215 may be manufactured by a resin molding method and be formed of a non-conductive material. As a resin material for the case 215, a thermosetting film such as a polyimide-based film, an epoxy-based film, or the like, may be used. Alternatively, as a molding resin, epoxy molding compound (EMC), epoxy sheet molding (ESM), polyphenylene oxide (PPO), silicon film, or the like, may be used.

The terminal 210 may be electrically connected to the device 220 through a bonding surface 211 thereof and be electrically connected to the electrode 231 of the board through the mounting surface 212 thereof. A material of the terminal 210 may have an influence on efficiency of power supply between the terminal 210 and the device 220 and between the terminal 210 and the board 230.

Therefore, the terminal 210 may be formed of a conductive material. In detail, the terminal 210 may be formed of a conductive material containing aluminum (Al), copper (Cu), or the like, and a surface of the terminal 210 may be plated with tin (Sn), gold (Au), nickel (Ni), or lead (Pb). However, the present disclosure is not limited thereto.

As described above, the device package 200 according to an exemplary embodiment in the present disclosure may include the terminals 210 including one or more protrusion parts 213 formed on the mounting surfaces 212 thereof bonded to the board 230 in order to increase the adhesive strength between the terminals 210 and the board 230. A bonding area between the terminal 210 and the electrode 231 of the board may be increased by the protrusion part 213 to improve the adhesive strength.

In addition, in the case in which the board 230 is bent, stress occurring in a bonding part between the terminal 210 and the board 230 may be dispersed by the area increased by the protrusion part 213 and a shape of the protrusion part, such that the adhesive strength may be improved.

Since the crystal device used in the electronic apparatus in which the multifunctionality and the complexity are demanded is connected to the board through a plurality of electrodes, a mounting space may be narrow. Therefore, a crack may occur in a bonding part between the crystal device and the board due to thermal impact caused by heat generated when the electronic apparatus is used. Therefore, it may be necessary to increase adhesive strength between the terminal of the device package including the crystal device and the board in order to prevent the occurrence of the crack due to the thermal impact.

The terminal according to an exemplary embodiment in the present disclosure is used, such that the adhesion strength may be increased. Therefore, the device may be stably mounted even in a narrow mounting area. Therefore, the mounting area may be decreased, such that a degree of freedom in a design of the electronic apparatus may be increased, and the adhesive strength may be increased, such that reliability of the electronic apparatus may be improved.

The protrusion part 213 included in the terminal 210 may have a form protruded from the mounting surface 212 on which the terminal 210 is mounted on the board 230. The number of protrusion parts 213 may be one or plural.

The protrusion part 213 may have a hemispherical shape or a polygonal pillar shape. In this case, any one polygonal pillar shape may be repeatedly formed or several polygonal pillar shapes may be alternately or randomly formed. In addition, the protrusion part 213 may have a stripe pillar shape.

The shape and the number of protrusion parts 213 are not particularly limited. The shape and the number of protrusion parts 213 may be various depending on a kind of device 220 on which the terminals 210 are disposed, a kind of board 230 on which the device 220 is mounted, or the like.

Since a more detailed description for the protrusion part 213 included in the terminal 210 has been provided above, it will be omitted in order to avoid an overlapped description.

The terminals 210 may be disposed at four corners of a lower surface of the device 220, respectively. As a result, the device 220 may be stably bonded to the board 230.

### Piezoelectric Device Package

Next, a piezoelectric device package 300 including a terminal 310 according to another exemplary embodiment in the present disclosure will be described. The piezoelectric device package 300 may be included in the device package 200 described above, and will be described below in detail.

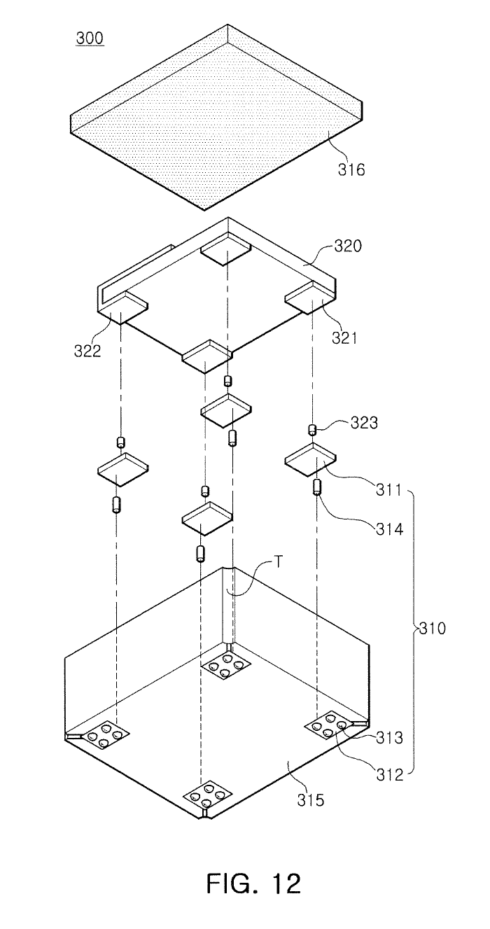

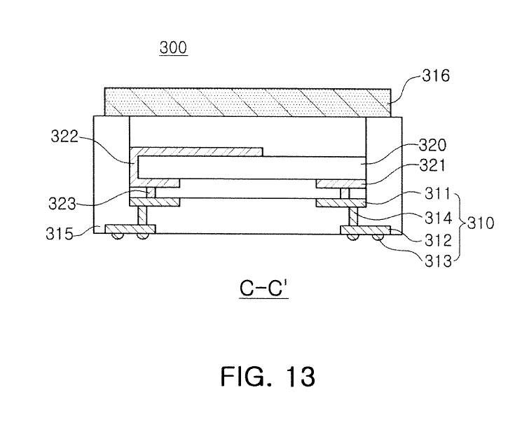

FIG. 11 is a perspective view of a piezoelectric device package 300 including a terminal 310 according to a ninth exemplary embodiment in the present disclosure; FIG. 12 is an exploded perspective view of the piezoelectric device package of FIG. 11 illustrating a connection relationship between a piezoelectric device 320 and the terminal 310. FIG. 13 is a cross-sectional view of the piezoelectric device package 300 of FIG. 11 taken along line C-C′, illustrating a coupling relationship between an input or output terminal 321 or 322 of the piezoelectric device and a first terminal 311 and disposition of connection electrodes 323 and 314.

Referring to FIGS. 11 through 13, the piezoelectric device package 300 according to a ninth exemplary embodiment in the present disclosure may include a case 315, a piezoelectric device 320 formed in the case 315, input and output terminals 321 and 322 disposed on outer surfaces of the piezoelectric device 320, and terminals 310 disposed in the case 315, wherein the terminals 310 include first terminals 311 disposed in the case 315 so as to be electrically connected to the input and output terminals 321 and 322 of the piezoelectric device 320 and second terminals 312 electrically connected to the first terminals 311 and disposed on an outer surface of the case 315 so as to be electrically connected to electrodes of a board on which the case 315 is mounted, the second terminals 312 including one or more protrusion parts 313 formed on a mounting surface on which they are mounted on the board.

The piezoelectric device 320 may include the output terminal 322 and the input terminal 321 formed on an upper surface and a lower surface thereof, respectively. Although not shown, the piezoelectric device 320 may be electrically connected to the input terminal 321 and the output terminal 322 thereof by the terminals 310 formed in the case 315 and be connected to an external integrated circuit via the board.

The input terminal 321 and the output terminal 322 of the piezoelectric device may be extended and formed at lower corners of the piezoelectric device 320, respectively.

The piezoelectric device 320 may be connected to the first terminal 311 of the terminal 310 using the connection electrode 323 of the piezoelectric device. The first terminal 311 may be connected to the second terminal 312 through the connection electrode 314 of the terminal. Although not shown, the second terminal 312 may be electrically connected to the electrode of the board on which the piezoelectric device 320 is to be mounted. As a result, the piezoelectric device 320 may be connected to an external integrated circuit.

As a method of bonding the terminal 310 to the electrode of the board, there may be a method of forming the solders on the electrode of the board, disposing the terminal, and performing a reflow process to bond the terminal to the electrode of the board, a method of adhering a bonding film between the electrode of the board and the terminal to bond the terminal to the electrode of the board, a method of welding the electrode of the board and the terminal to each other, and the like. However, the present disclosure is not limited thereto.

The case 315 may be formed of a non-conductive material. As a material for the case 315, a thermosetting film such as a polyimide based film, an epoxy based film, or the like, may be used. Alternatively, as a molding resin, epoxy molding compound (EMC), epoxy sheet molding (ESM), polyphenylene oxide (PPO), silicon film, or the like, may be used.

The first and second terminal 311 and 312 of the terminal 310 may be electrically connected to the piezoelectric device 320 and the electrode of the board. Materials of the first and second terminals 311 and 312 may have an influence on efficiency of power supply between the terminal 310 and the piezoelectric device 320 and between the terminal 310 and the board.

Therefore, the first and second terminals 311 and 312 may be formed of a conductive material. In detail, the first and second terminals 311 and 312 may be formed of a conductive material containing aluminum (Al), copper (Cu), or the like, and surfaces of the terminals 311 and 312 may be plated with tin (Sn), gold (Au), nickel (Ni), or lead (Pb). However, the present disclosure is not limited thereto.

As described above, the piezoelectric device package 300 according to an exemplary embodiment in the present disclosure may include the terminals 310 including one or more protrusion parts 313 formed on bonding surfaces of the second terminals 312 bonded to the board in order to increase the adhesive strength between the terminals 310 and the board. A bonding area between the terminal 310 and the electrode of the board may be increased through the protrusion part 313 to improve the adhesive strength. In addition, in the case in which the board is bent, stress occurring in a bonding part between the terminal 310 and the board may be dispersed by the area increased by the protrusion part 313 and a shape of the protrusion part, such that the adhesive strength may be improved.

The terminal according to an exemplary embodiment in the present disclosure is used, such that the adhesion strength may be increased. Therefore, the piezoelectric device may be stably mounted even in a narrow mounting area. Therefore, the mounting area may be decreased, such that a degree of freedom in a design of the electronic apparatus may be increased, and the adhesive strength may be increased, such that reliability of the electronic apparatus may be improved.

The protrusion part 313 included in the second terminal 312 of the terminal 310 may have a form protruded from the mounting surface on which the terminal is mounted on the board among surfaces of the second terminal 312. The number of protrusion parts included in the second terminal 312 may be one or plural.

The protrusion part included in the second terminal 312 may have a hemispherical shape or a polygonal pillar shape. In this case, any one polygonal pillar shape may be repeatedly formed or several polygonal pillar shapes may be alternately or randomly formed. The protrusion part included in the second terminal 312 may have a stripe pillar shape.

The shape and the number of protrusion parts included in the second terminal 312 are not particularly limited. The shape and the number of protrusion parts included in the second terminal 312 may be various depending on a kind of piezoelectric device 320 on which the terminals 310 including the second terminal 312 are disposed, a kind of board on which the piezoelectric device 320 is mounted, or the like.

Since a more detailed description for the protrusion part 313 included in the second terminal 312 has been provided above, it will be omitted in order to avoid an overlapped description.

The second terminals 312 of the terminal may be disposed at four corners of a lower surface of the piezoelectric device package 300, respectively. As a result, the piezoelectric device package may be stably bonded to the board.

At least one of the second terminals 312 of the terminal 310 may be electrically connected to a cover member 316 using a penetration part T.

The cover member 316 may be formed of a material having good conductivity to serve as a ground of the piezoelectric device 320.

The cover member 316 may serve as the ground to prevent noise when the piezoelectric device package 300 generates a frequency and to significantly decrease an influence from the outside.

The cover member 316 may be formed of copper, but is not limited thereto.

As set forth above, the device and the device package according to exemplary embodiments in the present disclosure may be stably mounted on the board by including the protrusion part formed on the bonding surface of the terminal to improve the adhesive strength. In addition, the adhesive strength may be improved to decrease the mounting area, such that a degree of freedom in a design of the electronic apparatus may be increased, and the adhesive strength may be increased, such that reliability of the electronic apparatus may be improved.

While exemplary embodiments have been shown and described above, it will be apparent to those skilled in the art that modifications and variations could be made without departing from the scope of the invention as defined by the appended claims.

What is claimed is:

1. A device comprising:
a terminal; and
one or more protrusion parts disposed on a mounting surface of the terminal.

2. The device of claim 1, wherein the protrusion part is protruded from the mounting surface of the terminal.

3. The device of claim 1, wherein the protrusion part has a stripe shape when viewed on a plane.

4. The device of claim 1, wherein the protrusion part has a circular shape when viewed on a plane.

5. The device of claim 1, wherein the protrusion part has a polygonal shape when viewed on a plane.

6. The device of claim 1, wherein the terminal is formed of a conductive material.

7. The device of claim 1, wherein it is a crystal device.

8. The device of claim 1, further comprising an electrode exposed to the outside of the device to thereby be electrically connected to the terminal.

9. A device package comprising:
a board;
a terminal electrically connected to an electrode of the board;
a device electrically connected to the terminal; and
a case disposed so as to enclose the device,
wherein the terminal includes one or more protrusion parts formed on a mounting surface by which the terminal is mounted on the board.

10. The device package of claim 9, wherein the protrusion part has a form protruded from the mounting surface on which the terminal is mounted on the board among surfaces of the terminal.

11. The device package of claim 9, wherein second terminals are disposed at four corners of a lower surface of the device, respectively.

12. The device package of claim 9, wherein the terminal is formed of a conductive material.

13. The device package of claim 9, wherein the case is formed of a non-conductive material.

14. The device package of claim 9, wherein the device is a piezoelectric device.

15. The device package of claim 9, wherein the device is a crystal device.

16. The device package of claim 9, further comprising an electrode exposed to the outside of the device to thereby be electrically connected to the terminal.
